(19) United States
(12) Patent Application Publication
(10) Pub. No.: US 2024/0045332 A1
(43) Pub. Date: Feb. 8, 2024

(54) METHOD OF FORMING PHOTOSENSITIVE ORGANOMETALLIC OXIDES BY CHEMICAL VAPOR POLYMERIZATION

(71) Applicant: Tokyo Electron Limited, Tokyo (JP)

(72) Inventors: Kandabara Tapily, Albany, NY (US); Nobuo Matsuki, Nirasaki City (JP)

(21) Appl. No.: 18/216,168

(22) Filed: Jun. 29, 2023

Related U.S. Application Data
(60) Provisional application No. 63/394,471, filed on Aug. 2, 2022.
(60) Provisional application No. 63/442,079, filed on Jan. 30, 2023.
(60) Provisional application No. 63/456,343, filed on Mar. 31, 2023.

(51) Int. Cl. G03F 7/039; C08F 230/04; G03F 7/038; G03F 7/16; G03F 7/20; H01L 21/027

(52) U.S. Cl. CPC G03F 7/039; C08F 230/04; G03F 7/038; G03F 7/168; G03F 7/2004; H01L 21/0274

(57) ABSTRACT

Embodiments of methods are provided to form an EUV-active photoresist film for use in EUV photolithographic processes. The methods disclosed herein may generally include forming an extreme ultraviolet (EUV)-active photoresist film on a surface of the semiconductor substrate, where the EUV-active photoresist film is an organometallic oxide with polymerized carbon-carbon bonds, and patterning the EUV-active photoresist film with EUV lithography to form a patterned photoresist on the surface of the semiconductor substrate.

This application claims priority to U.S. Provisional Patent Application Ser. No. 63/394,471, filed Aug. 2, 2022, U.S. Provisional Patent Application Ser. No. 63/442,079, filed Jan. 30, 2023, and U.S. Provisional Patent Application Ser. No. 63/456,343, filed Mar. 31, 2023, each of which is entitled “Method of Forming Photosensitive Organometallic Oxides by Chemical Vapor Polymerization”; the disclosure of which is expressly incorporated herein, in its entirety, by reference.

### TECHNICAL FIELD

The present invention relates generally to extreme ultraviolet (EUV) lithography, and, in particular embodiments, to EUV-active films and methods of formation thereof.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

A common patterning method is to use a photolithography process to expose a coating of photoresist over the target layer to a pattern of actinic radiation and then transfer the relief pattern to the target layer or an underlying hard mask layer formed over the target layer. With this technique, the minimum feature size would be limited by the resolution of the optical system. Scaling of feature sizes for advanced technology nodes is driving lithography to improve resolution. For sub-10 nm technology nodes (for example, 7 nm and 5 nm technology nodes), 13.5 nm extreme ultraviolet (EUV) lithography is commonly used to pattern a photoresistive film with EUV radiation.

EUV lithography techniques offer significant advantages in patterning sub-10 nm features with its high optical resolution. However, one major engineering challenge for EUV lithography is that photoresists developed for conventional photolithography systems may not satisfy the cost and/or quality requirements for patterning sub-10 nm features. For example, chemically amplified resist (CAR) or similar polymer resists, which are commonly used in 193 nm lithography, are typically produced using liquid based spin-on techniques that consume a significant amount of complex metal cluster precursors, resulting in very high cost. CARs also tend to have low absorption coefficients at 13.5 nm, and thus, may suffer poor sensitivity. Further, the diffusion of photo-activated species in CARs may cause blurring and increase line-edge roughness (LER) in the subsequently formed pattern.

As an alternative to CARs, vapor-deposited metal oxide-containing films have been investigated for use as EUV-active hardmasks in EUV lithography techniques. For example, U.S. Pat. No. 9,996,004, entitled “EUV Photopatterning of Vapor-Deposited Metal Oxide-Containing Hardmasks”, describes various processes for forming metal oxide-containing hardmasks utilized for EUV patterning. In the ′004 Patent, an EUV-sensitive metal oxide-containing film is vapor deposited on a semiconductor substrate by chemical vapor deposition (CVD) or atomic layer deposition (ALD). During the deposition process, an organotin oxide precursor is reacted with a carbon dioxide-containing plasma at a relatively high deposition temperature (in one example, between 250° C. and 350° C.) to deposit the EUV-sensitive metal oxide-containing film on the semiconductor substrate. After CVD/ALD deposition, the metal oxide-containing film is transferred to an EUV patterning tool and patterned via direct EUV exposure (i.e., without the use of a photoresist), followed by pattern development, to form a metal oxide-containing hardmask. The processes described in the ′004 Patent suffer from various disadvantages. For example, the deposition processes described in the ′004 Patent react various organotin oxide precursors with an oxidizer (e.g., carbon dioxide or carbon monoxide) in a typical CVD/ALD process to form a solid metal oxide-containing film on the semiconductor substrate. The oxidizer utilized within the CVD/ALD deposition process increases the density of the metal oxide-containing film and decomposes the Sn—R bonds (where —R is —CxHy, —OCxHy, —CI or —NCxHy) in organo tin precursors, which creates weak and unstable bonds (for example, Sn—OH and Sn—O—Sn bonds), which deteriorate EUV photosensitivity of the subsequently formed hardmask.

Innovations on EUV photolithographic techniques are needed to satisfy the cost and quality requirements for patterning at the sub-10 nm node regime. To meet these needs, it may be desirable to develop a new class of photoresists for EUV lithography with better performance.

### SUMMARY

The present disclosure provides improved processes and methods for forming an EUV-active photoresist film, comprising an organometallic oxide polymerized with carbon-carbon bonds. In the present disclosure, chemical vapor polymerization (CVP) is utilized to deposit a non-solid, organometallic oxide polymer layer onto a surface of the semiconductor substrate. In some embodiments of the present disclosure, the non-solid organometallic oxide polymer layer may be deposited onto the substrate surface by a low temperature, low ion energy plasma process, which exposes the substrate surface to a plasma-excited vapor comprising a metal precursor having carbon-carbon double bonds. The low temperature, low ion energy plasma process forms a non-solid, organometallic oxide polymer layer (containing liquid-like oligomer units) having carbon-carbon bonds on the substrate surface. The semiconductor substrate is then subjected to a heat treatment (for example, a thermal bake) to further polymerize the non-solid organometallic oxide polymer layer and form an organometallic oxide polymer film with carbon-carbon bonds, the organometallic oxide polymer film forming the EUV-active photoresist film.

The processes and methods disclosed herein provide various advantages over conventional methods for forming an EUV-active photoresist film. For example, the disclosed methods provide an EUV-active photoresist having a higher EUV absorbance, better photoresist sensitivity, and better etch resistance compared to conventional chemically amplified resists (CARs). In some embodiments, the higher EUV absorbance may advantageously enable the thickness of the EUV-active photoresist, which is required for acceptable performance, to be reduced. Compared to conventional metal oxide resists, the disclosed methods provide an EUV-active photoresist with greater mechanical strength and photosensitivity.

According to one embodiment, a method is provided herein for processing a semiconductor substrate. The method may generally begin by forming an extreme ultraviolet (EUV)-active photoresist film on a surface of the semiconductor substrate, wherein the EUV-active photoresist film comprises an organometallic oxide with polymerized carbon-carbon bonds. In some embodiments, the organometallic oxide may contain a central metal atom selected from a group consisting of tin (Sn), zirconium (Zr), indium (In), antimony (Sb), bismuth (Bi), zinc (Zn), hafnium (Hf), aluminum (Al) and combinations thereof. In one example embodiment, the organometallic oxide may contain tin (Sn). After the EUV-active photoresist film is formed, the method may further include patterning the EUV-active photoresist film with EUV lithography to form a patterned photoresist on the surface of the semiconductor substrate.

In some embodiments, the EUV-active photoresist film may be formed by: (a) exposing the surface of the semiconductor substrate to a plasma-excited vapor comprising a metal precursor having carbon-carbon double bonds to form a non-solid organometallic oxide polymer layer on the surface of the semiconductor substrate, and (b) heat-treating the semiconductor substrate to further polymerize the non-solid organometallic oxide polymer layer and form the organometallic oxide with polymerized carbon-carbon bonds.

In some embodiments, exposing the surface of the semiconductor substrate to the plasma-excited vapor may be performed without exposing the substrate to an oxidizer, such as oxygen (O₂), ozone (O₃), water (H₂O), hydrogen peroxide (H₂O₂), carbon dioxide (CO₂) or carbon monoxide (CO). In some embodiments, exposing the surface of the semiconductor substrate to the plasma-excited vapor may be performed at relatively low ion energies (for example, less than 50 eV, and in some embodiments, between about 0 eV and about 5 eV) and relatively low substrate temperatures (for example, less than about 100° C., and in some embodiments, between about −50° C. and about 0° C.). In such embodiments, the non-solid organometallic oxide polymer layer formed on the substrate surface may include liquid-like oligomer units having carbon-carbon bonds.

In some embodiments, heat-treating the semiconductor substrate may include maintaining the semiconductor substrate at a substrate temperature between about 0° C. and about 200° C. In other embodiments, heat-treating the semiconductor substrate may include maintaining the semiconductor substrate at a substrate temperature between about 200° C. and about 400° C. During the heat-treating step, the liquid-like oligomer units having carbon-carbon bonds polymerize to form the organometallic oxide with polymerized carbon-carbon bonds.

According to another embodiment, another method is provided herein for processing a semiconductor substrate. The method may generally begin by exposing a surface of the semiconductor substrate to a plasma-excited vapor comprising a metal precursor having carbon-carbon double bonds to form a non-solid organometallic oxide polymer layer on the surface of the semiconductor substrate. During said exposing, the semiconductor substrate is maintained at a first substrate temperature between about −50° C. and about 0° C. The method may further include heat-treating the semiconductor substrate at a second substrate temperature between about 0° C. and about 400° C. to further polymerize the non-solid organometallic oxide polymer layer and form an organometallic oxide with polymerized carbon-carbon bonds. In some embodiments, the second substrate temperature may be between about 0° C. and about 200° C. In other embodiments, the second substrate temperature may be between about 200° C. and about 400° C. The organometallic oxide formed as a result of the exposing and heat treating steps is an extreme ultraviolet (EUV)-active photoresist film. Next, the method may include patterning the EUV-active photoresist film with EUV lithography to form a patterned photoresist on the surface of the semiconductor substrate.

The methods described herein may utilize a wide variety of metal precursors. For example, the metal precursor may include a metal alkoxide. In some embodiments, the metal precursor may contain tin (Sn) and have the formula Sn_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. In one example, the metal precursor may include SnR1(O—R2)₃, SnR1₂ (O—R2)₂, or SnHR1(O—R2)₂, where R1: CH₃, C₂H₃, C₃H₅, C₄H₇, or C₆H₆, and R2: CH₃, C₂H₅, C₃H₇, or C₄H₉. In another example, the metal precursor may include SnCH₃^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, or SnCH₃(C₂H₃)(O—CH₃)₂. In other embodiments, the metal precursor may contain tin (Sn) and have the formula SnₓC_{y}H_{z}, where x, y, and z are arbitrary integers of 1 or more. For example, the metal precursor may be selected from the group consisting of Sn(CH₃)₄, Sn(C₂H₅)₄, SnH(CH₃)₃, and SnH(C₂H₅)₃. In further embodiments, the metal precursor may contain a metal (M) and have the formula M_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time.

In some embodiments, the plasma-excited vapor may further include an additive precursor. For example, when the metal precursor contains tin (Sn) and has the formula Sn_{α}O_{β} (O—CₘHₙ)ΓCₓH_{y}, the additive precursor added to the plasma-excited vapor may contain tin (Sn) and have a formula Sn_{α}CₓH_{y}, where m, n, and a are arbitrary integers of 1 or more. When the metal precursor contains a metal (M) and has the formula M_{α}O_{β} (O—CₘHₙ)ΓCₓH_{y}, the additive precursor added to the plasma-excited vapor may contain a metal (M) and have a formula MαCxHy, where m, n, and α are arbitrary integers of 1 or more.

In some embodiments, the plasma-excited vapor may further include an additive monomer to increase a photo-sensitivity of the EUV-active photoresist film to EUV radiation. In some embodiments, the additive monomer may include a hydrocarbon containing carbon-oxygen double bonds. For example, the additive monomer may include a ketone, an aldehyde, or an ester.

Various embodiments of methods are provided herein for processing a semiconductor substrate, and more specifically, for forming an EUV-active photoresist film comprising an organometallic oxide polymerized with carbon-carbon bonds. Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed inventions. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages

thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A is a process flow diagram illustrating an example process flow to form an EUV-active photoresist film on a surface of a semiconductor substrate in accordance with one embodiment of the present disclosure;

FIG. 1B illustrates example chemistry that can be utilized for the chemical vapor polymer deposition and heat treatment steps shown in FIG. 1A, including an example metal precursor that can be used during the plasma process step to form an example non-solid, organometallic oxide polymer layer on the substrate surface, and an example EUV-active photoresist film that can be formed during the subsequently performed heat treatment step;

FIG. 2A is a process flow diagram illustrating an example process flow to pattern and develop the EUV-active photoresist film formed in FIG. 1A;

FIG. 2B illustrates example reactions that occur during the EUV exposure and (optional) post exposure bake (PEB) steps shown in FIG. 2A;

FIG. 3 is a flowchart diagram illustrating one embodiment of a method for processing a semiconductor substrate in accordance with the present disclosure; and

FIG. 4 is a flowchart diagram illustrating another embodiment of a method for processing a semiconductor substrate in accordance with the present disclosure.

### DETAILED DESCRIPTION OF ILLUSTRATIVE EMBODIMENTS

The present disclosure relates to photolithographic processes, more particularly, to methods of forming an extreme ultraviolet (EUV)-active photoresist comprising an organometallic moiety for use in EUV photolithographic processes.

Embodiments of the present disclosure provide improved process flows and methods of forming an EUV-active photoresist film comprising an organometallic oxide polymerized with carbon-carbon bonds. In the present disclosure, chemical vapor polymerization (CVP) is utilized to deposit a non-solid, organometallic oxide polymer layer onto a surface of the semiconductor substrate. In some embodiments, the non-solid organometallic oxide polymer layer may be deposited onto the substrate surface by a low temperature, low ion energy plasma process, which exposes the substrate surface to a plasma-excited vapor comprising a metal precursor having carbon-carbon double bonds. The low temperature, low ion energy plasma process forms a non-solid, organometallic oxide polymer layer (containing liquid-like oligomer units) having carbon-carbon bonds on the substrate surface. The semiconductor substrate is then subjected to a heat treatment (e.g., a thermal bake) to further polymerize the non-solid organometallic oxide polymer layer and form an organometallic oxide polymer film with carbon-carbon bonds. The organometallic oxide polymer film in various embodiments responds to an EUV exposure, which induces changes of material properties that enable portions of the organometallic oxide polymer film to be removed during subsequently performed patterning and developing steps to form a patterned photoresist on the surface of the semiconductor substrate.

The methods described in this disclosure may be used to create an organometallic oxide polymerized with carbon-carbon bonds as an extreme ultraviolet (EUV)-active photoresist. The EUV-active photoresist disclosed herein provides various advantages over conventional photoresists used for EUV lithography. For example, the EUV-active photoresist disclosed herein has a higher EUV absorbance, and thereby better resist sensitivity, compared to conventional chemically amplified resists (CARs). In some embodiments, the higher EUV absorbance may enable the thickness of the photoresist required for an acceptable performance to be decreased. The EUV-active photoresist described in this disclosure may also advantageously exhibit an etch resistance that is better than conventional CARs. In addition, the methods herein may enable a uniform chemical composition of the EUV-active photoresist, which may be beneficial in mitigating issues of blur or line edge roughness.

Further, the EUV-active photoresist in accordance with various embodiments of the present disclosure may be formed over a substrate and developed by dry or wet processes. While conventional techniques used to apply and develop CARs are based on wet processes, dry processes for the formation and developing of the EUV-active photoresist disclosed herein provide better process control at the nanoscale than a wet process (e.g., when forming features that are a few nanometers or sub-nanometer in critical dimension). Although dry processes are preferred, conventional spin-on processes for deposition and wet processes using developing solutions are also available for the methods of this disclosure.

In addition to CARs, the EUV-active photoresist disclosed herein provides various advantages over conventional vapor-deposited metal oxide-containing films, such as those described in the ′004 Patent. Unlike the conventional processes disclosed in the ′004 Patent, which react various organotin oxide precursors with an oxidizer (for example, carbon dioxide or carbon monoxide) in a typical CVD/ALD process to form a solid metal oxide-containing film on the semiconductor substrate, the improved process flows and methods disclosed herein use a low temperature, low ion energy plasma process, which exposes the substrate surface to a plasma-excited vapor comprising a metal precursor having carbon-carbon double bonds to deposit a non-solid, organometallic oxide polymer layer (containing liquid-like oligomer units) having carbon-carbon bonds onto the substrate surface. The carbon-carbon double bonds provided within the metal precursor enhance polymerization during the subsequently performed heat treatment step to form the organometallic oxide polymer film with carbon-carbon bonds. The presence of carbon-carbon bonds in the organometallic oxide polymer film increases the mechanical strength and stability of the EUV-active photoresist disclosed herein compared to conventional vapor-deposited metal oxide-containing films containing Sn—OH and Sn—O—Sn bonds.

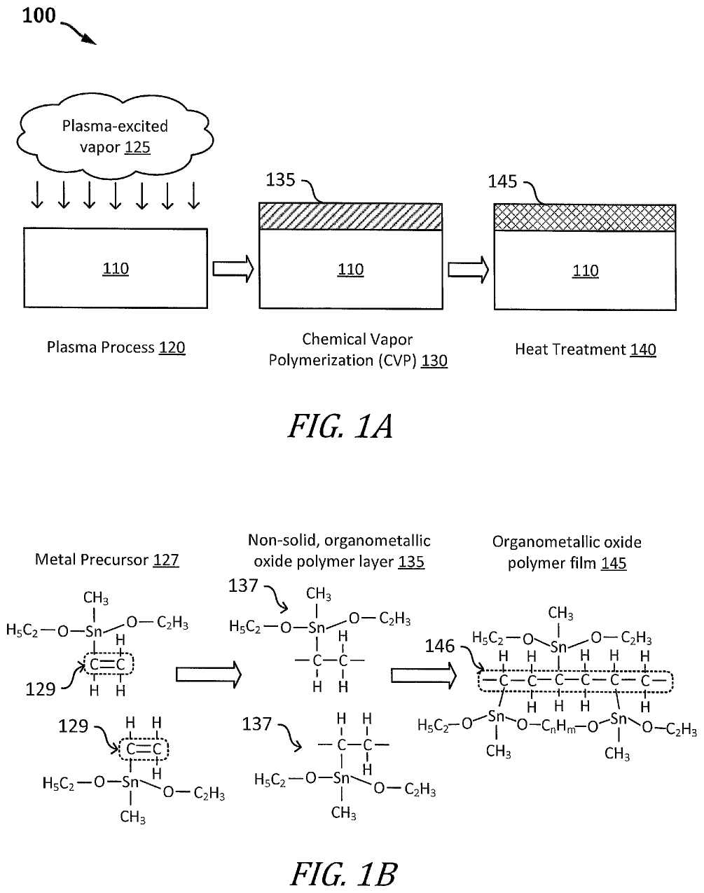

Turning now to the Drawings, FIG. 1A illustrates one embodiment of a process flow 100 used to form an EUV-active photoresist on a surface of a semiconductor substrate in accordance with one embodiment of the present disclosure. As shown in FIG. 1A, process flow 100 begins by performing a low temperature, low ion energy plasma process 120 that exposes the surface of the semiconductor substrate 110 to a plasma-excited vapor 125 containing a metal precursor having carbon-carbon double bonds. In some embodiments, an additive precursor may also be included within the plasma-excited vapor 125. Examples of suitable metal precursors and additive precursors are discussed in more detail below. During the plasma process 120, the semiconductor substrate 110 is maintained at a relatively low substrate temperature (for example, a substrate temperature less than about 100° C., and more preferably, less than about 0° C.), while ions within the plasma-excited vapor 125 are maintained at a relatively low ion energy (for example, an ion energy less than about 50 eV, and more preferably, between about 0 eV and about 5 eV). Under these conditions, a non-solid organometallic oxide polymer layer 135 is deposited onto the surface of the semiconductor substrate 110 via chemical vapor polymerization (CVP) 130.

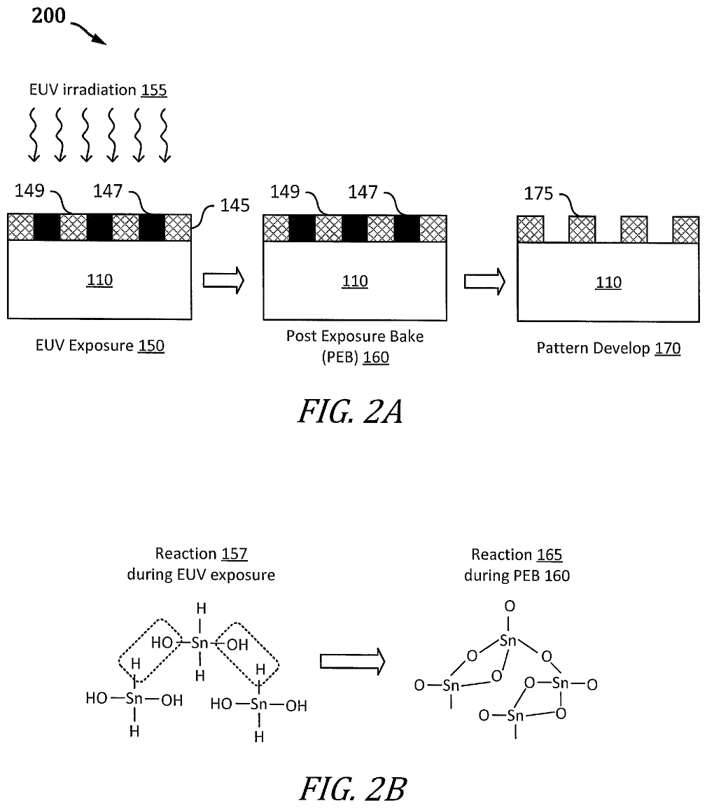

Once the non-solid organometallic oxide polymer layer 135 is deposited onto the substrate surface, the semiconductor substrate 110 is subjected to a heat treatment 140 (for example, a thermal bake) to further polymerize the non-solid organometallic oxide polymer layer 135 and form an organometallic oxide polymer film 145 having carbon-carbon bonds on the substrate surface. The organometallic oxide polymer film 145 formed in accordance with the process flow 100 is an EUV-active photoresist film that can be patterned with EUV lithography and developed as shown, for example, in FIG. 2A and described below.

As noted above, the plasma process 120 shown in FIG. 1A is performed at relatively low substrate temperatures and ion energies. According to one embodiment, the substrate temperature during the plasma exposure can, for example, be less than about 100° C. In other embodiments, the substrate temperature during the plasma exposure can be between about −50° C. and about 0° C., between about −50° C. and about −25° C., or between about −25° C. and about 0° C. According to one embodiment, the ion energy of the ions within the plasma-excited vapor 125 can be about 50 eV. In other embodiments, the ion energy can be less than 50 eV, for example, between about 0 eV and about 50 eV or between about 0 eV and about 5 eV. It is contemplated that the use of ion energy between about 0 eV and about 5 eV is beneficial to minimize plasma damage to the non-solid organometallic oxide polymer layer 135 deposited onto the substrate surface during the plasma process 120.

The plasma process 120 shown in FIG. 1A can be performed within a wide variety of plasma processing systems and/or chambers. In some embodiments, the plasma process 120 may be performed within a capacitively coupled plasma (CCP) processing chamber. In some examples, a 13.56 MHz-60 MHz CCP source with power between about 10 W and about 500 W may be used to create plasma conditions that include an ion energy of about 50 eV (or less). A gas pressure within the CCP processing chamber can, for example, be between about 100 mTorr and about 20 Torr. The substrate temperature can be less than about 100° C., as set forth above.

In other embodiments, a plasma processing system containing a remote plasma source can be used to perform the plasma process 120 shown in FIG. 1A. Examples of such plasma processing systems include the use of remote plasma sources using radio frequency (RF), very high frequency (VHF), and microwave frequency (MWF). A plasma processing system containing a remote plasma source can include: (a) a vacuum chamber that is divided into a plasma space and a separate wafer space by a separation plate with plurality of holes, or (b) a plasma source that is attached to the vacuum chamber. A remote plasma source may be desirable in some embodiments, since it is effective in minimizing or eliminating exposure of the substrate to high energy ions.

The heat treatment 140 shown in FIG. 1A includes heat-treating the semiconductor substrate 110 containing the non-solid organometallic oxide polymer layer 135 formed thereon to further polymerize the non-solid organometallic oxide polymer layer 135 and form the organometallic oxide with polymerized carbon-carbon bonds. A wide variety of methods may be utilized to heat treat the semiconductor substrate 110. According to one embodiment, the heat treatment 140 step may be performed within a vacuum chamber at an elevated substrate temperature. In such embodiments, heat-treating may be performed under reduced pressure in the presence of an additive gas that can, for example, include hydrogen bromide (HBr), hydrogen (H₂), helium (He), argon (Ar), neon (Ne), xenon (Xe), nitrogen (N₂), and/or carbon monoxide (CO). In one example, the heat-treating may be performed using a substrate holder that acts as a hot-plate. Further, the heat-treating may be performed in the absence of plasma excitation or using plasma excitation of the additive gas. In another example, the heat-treating may be performed by optical means such laser heating. According to one embodiment, the substrate temperature during the heat treatment 140 step can be between about 0° C. and about 400° C. In other embodiments, the substrate temperature during the heat treatment 140 step can be between about 0° C. and about 50° C., between about 50° C. and about 100° C., between about 100° C. and about 200° C., between about 200° C. and about 300° C., between about 0° C. and about 200° C., or between about 200° C. and about 400° C. Other methods for performing the polymerization shown in FIG. 1A can include, but are not limited to, using a hot filament above the substrate or using activation by e-beam, UV, EUV, High NA EUV, or Next Gen high NA/ Hyper NA EUV.

A wide variety of metal precursors may be used during the plasma process 120 shown in FIG. 1A to form an EUV-active photoresist film. For example, a metal precursor comprising an EUV metal may be used. In the present disclosure, the term “EUV metal” may refer to a metal component with a high EUV absorption coefficient. According to one embodiment, the EUV metal may comprise tin (Sn). In other embodiments, the EUV metal may comprise zirconium (Zr), indium (In), antimony (Sb), bismuth (Bi), hafnium (Hf) or aluminum (Al). According to one embodiment, an organometallic oxide in the EUV-active photoresist film contains a central metal atom selected from the group consisting of tin (Sn), zirconium (Zr), indium (In), antimony (Sb), bismuth (Bi), zinc (Zn), hafnium (Hf), aluminum (Al) and combinations thereof. In the following description, various embodiments including figures are described using tin (Sn) as an exemplary metal component for the EUV-active photoresist film. It is recognized, however, that the metal component is not limited to tin (Sn) and other metals may also be present in the EUV-active photoresist film.

According to one embodiment, the metal precursor contains tin (Sn) and has the formula Sn_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. Examples include SnR1(O—R2)₃, SnR1₂(O—R2)₂, SnHR1(O—R2)₂, where R1: CH₃, C₂H₃, C₃H₅, C₄H₇, or C₆H₆, and R2: CH₃, C₂H₅, C₃H₇, or C₄H₉. Additional examples of a metal precursor containing tin (Sn) include SnCH₃^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, and SnCH₃(C₂H₃)(O—CH₃)₂. Other examples of a metal precursor containing tin (Sn) include Sn(C₂H₄O₂) and Sn(OR)₂, where R may be selected from CH₃, C₂H₅ and C₄H₉. Still other examples include a mixture of Sn(N(CH₃)₂)₄ and HOCH₂CH₂OH.

According to another embodiment, the metal precursor contains tin (Sn) and has the formula SnₓC_{y}H_{z}, where x, y, and z are arbitrary integers of 1 or more. In one example, the metal precursor is selected from the group consisting of Sn(CH₃)₄, Sn(C₂H₅)₄, SnH(CH₃)₃, and SnH(C₂H₅)₃. In such an embodiment, the plasma-excited vapor 125 containing the metal precursor can further include an additive gas such as, but not limited to, hydrogen (H₂), helium (He), argon (Ar), neon (Ne), krypton (Kr), nitrogen (N₂) or acetylene (C₂H₂).

According to yet another embodiment, the metal precursor contains a metal (M) and has the formula M_{α}O₆₂ (O—CₘHₙ)ΓCₓH_{y}, where m, n, and α are arbitrary integers of 1 or more, β, Γ, x, and y are arbitrary integers of 0 or more, and β and Γ are not 0 at the same time. Examples of metals having a high EUV absorption coefficient include, but are not limited to, tin (Sn), zirconium (Zr), antimony (Sb), indium (In), bismuth (Bi), zinc (Zn), hafnium (Hf), and aluminum (Al).

In some embodiments, the plasma-excited vapor 125 may include a metal precursor and an additive precursor. For example, when the metal precursor contains tin (Sn) and has the formula Sn_{α}O_{β} (O—CₘHₙ)ΓCₓH_{y}, the additive precursor added to the plasma-excited vapor 125 may contain tin (Sn) and have a formula Sn_{α}CₓH_{y}, where m, n, and α are arbitrary integers of 1 or more. When the metal precursor contains a metal (M) and has the formula M_{α}O_{β} (O—CₘHₙ)ΓCₓH_{y}, the additive precursor added to the plasma-excited vapor 125 may contain a metal (M) and have a formula MαCxHy, where m, n, and α are arbitrary integers of 1 or more.

According to one embodiment, the photo-sensitivity of the EUV-active photoresist film to EUV radiation may be amplified with an additive monomer by introducing species with carbon-oxygen double bonds (C═O) that surround the organometallic oxide. According to one embodiment, the plasma-excited vapor 125 can further contain an additive monomer, such as for example, a hydrocarbon containing C═O bonds. For example, the plasma-excited vapor 125 can further contain an additive monomer, such as a ketone, an aldehyde, or an ester, each of which contains a carbonyl group with a carbon-oxygen double bond (C═O). The ketone may be selected from the group consisting of acetone, methyl ethyl ketone, methyl propyl ketone, and methyl isopropyl ketone. The aldehyde may be selected from the group consisting of formaldehyde, acetaldehyde, and propionaldehyde. The ester may be selected from the group consisting of ethyl methanoate, methyl acetate, ethyl acetate, methyl acrylate, methyl butanoate, and methyl salicylate.

According to one embodiment, the plasma-excited vapor 125 can include a metal precursor containing tin (Sn) and the additive monomer can contain a ketone, an aldehyde, or an ester. According to one embodiment, the plasma-excited vapor 125 can further include an additive gas such as, but not limited to, hydrogen (H₂), helium (He), argon (Ar), neon (Ne), xenon (Xe), nitrogen (N₂), carbon monoxide (CO), ammonia (NH₃), or hydrogen sulfide (H₂S).

FIG. 1B illustrates example chemistry that can be utilized for the chemical vapor polymer deposition and heat treatment steps shown in FIG. 1A, including an example metal precursor 127 that can be used in the plasma process 120 to form an example non-solid, organometallic oxide polymer layer 135 on the surface of the semiconductor substrate 110. In FIG. 1B, the metal precursor 127 is an organic tin compound comprising a carbon-carbon double bond 129. The plasma excitation of the organic tin compound affects the carbon-carbon double bond 129 to form the non-solid organometallic oxide polymer layer 135 on the surface of the semiconductor substrate 110. In some embodiments, the plasma excitation can include an additive gas, such as for example hydrogen (H₂), helium (He), argon (Ar), neon (Ne), krypton (Kr), nitrogen (N₂), acetylene (C₂H₂), or carbon monoxide (CO).

FIG. 1B schematically shows two alkoxide based metal precursor molecules that are plasma-excited, without the presence of an oxidizer such as, oxygen (O₂), ozone (O₃), water (H₂O), hydrogen peroxide (H₂O₂), carbon dioxide (CO₂) or carbon monoxide (CO), to form the non-solid organometallic oxide polymer layer 135 on the surface of the semiconductor substrate 110. The plasma-based reaction forms liquid-like oligomer units 137 of an organometallic oxide on the substrate surface. A subsequent heat-treating (such as thermal baking) may be used to further polymerize the liquid-like oligomer units 137 of the non-solid organometallic oxide polymer layer 135 to form the organometallic oxide polymer film 145. As schematically shown in FIG. 1B, for example, the liquid-like oligomer units 137 of the non-solid organometallic oxide polymer layer 135 polymerize, upon heat-treating, to form an organometallic oxide with polymerized carbon-carbon bonds.

The chemical vapor polymerization (CVP) shown in FIGS. 1A and 1B, namely plasma excitation of the organic tin compound followed by the heat-treating of the semiconductor substrate, forms an organometallic oxide with polymerized carbon-carbon bonds, which increases the mechanical strength and photosensitivity of the EUV-active photoresist film.

In the example chemistry shown in FIG. 1B, the organic tin compound contains an Sn—O— unit that is protected by CₘHₙ ligands (for example, methane (CH₃) and ethyl radicals (C₂H₅)). The CₘHₙ ligands create carbon-carbon bondings to improve film stability and strength. The CmHn ligands also prevent Sn—O—Sn bondings in a given polymerized molecule from bonding with other Sn—O—Sn bondings in other polymerized molecules in the subsequently formed film. In another aspect, the CₘHₙ ligands promote solubility of portions of the EUV-active photoresist to be removed during a subsequently performed development step (for example, in the area of non EUV exposure). Further, organic tin compounds containing carbon-carbon double bonds 129 enhance polymerization during the heat treatment 140 step to form an organometallic oxide polymer film 145 with a polymerized carbon-carbon backbone 146 to increase the mechanical strength and photo-sensitivity of the EUV-active photoresist film. In some embodiments, the photo-sensitivity of the EUV-active photoresist film may be increased by adding a monomer to the plasma-excited vapor 125 (not shown in FIG. 1 B), wherein the additive monomer has carbon-oxygen double bonds (C═O) that surround the organometallic oxide.

FIG. 2A illustrates one embodiment of a process flow 200 used to pattern and develop an EUV-active photoresist film, such as the EUV-active photoresist film formed in FIG. 1A. FIG. 2B schematically shows example reactions that may occur during the EUV lithography process and (optional) heat treating step shown in FIG. 2A.

As shown in FIG. 2A, an EUV lithography process may be performed by exposing the surface of the semiconductor substrate 110 containing the EUV-active photoresist film (i.e., the organometallic oxide polymer film 145) to EUV irradiation 155 (e.g., at a wavelength of 13.5 nm) in an EUV exposure 150 step. The EUV lithography process may utilize a photomask (not shown) such that a photo-induced reaction occurs only in regions 147 of the EUV-active photoresist exposed to the EUV irradiation 155. The regions 147 of the EUV-active photoresist exposed to the EUV irradiation 155 are converted to a reacted photoresist. Regions 149 of the EUV-active photoresist not exposed to the EUV irradiation 155 remain unreacted. After the EUV exposure 150 step, an optional heat-treating step (for example, post-exposure bake (PEB)) 160 may be performed to stabilize the photoresist after EUV exposure by completing the reactions initiated during exposure and promote —(Sn—O—)n cross bonding in the EUV exposed area. In some embodiments, the optional heat-treating step 160 may prevent changes in line edge roughness (LER), line width roughness (LWR) and/or critical dimension (CD).

After completing the EUV exposure 150 and the optional post-exposure bake (PEB) 160, a developing step 170 may be performed to remove a portion of the EUV-active photoresist for patterning, thereby providing a patterned photoresist 175 on the substrate surface. The developing step 170 may be a wet or dry process. Conventionally, a portion of the EUV-active photoresist may be removed by treating the substrate with a developing solution to dissolve the reacted (in case of a positive tone resist) or unreacted (in case of a negative tone resist) regions of the EUV-active photoresist. A similar wet process may be applied in various embodiments. Alternately, a dry process may be used to remove the reacted or unreacted regions of the EUV-active photoresist in other embodiments. The dry process may comprise, for example, a selective plasma etch process or a thermal process, advantageously eliminating the use of a developing solution. In certain embodiments, the dry process may be performed using reactive ion etching (RIE) process or atomic layer etching (ALE).

FIG. 2B shows potential reactions that may occur during the EUV exposure 150 optional heat-treating step (post-exposure bake (PEB)) 160 steps shown in FIG. 2A. As shown in FIG. 2B, a first reaction 157 may occur during the EUV exposure 150 to form metal (for example, tin) alkoxide oligomers. During the EUV exposure 150 step, tin (Sn) atoms absorb EUV photons and expose secondary electrons to surrounding —C bondings to break Sn—C, O—C bonds, thus forming Sn—H and Sn—OH bonds, as shown in FIG. 2B. During the optional PEB 160, the converted Sn—H and Sn—OH bonds form a larger network of stable Sn—O—Sn bonds in a second reaction 165.

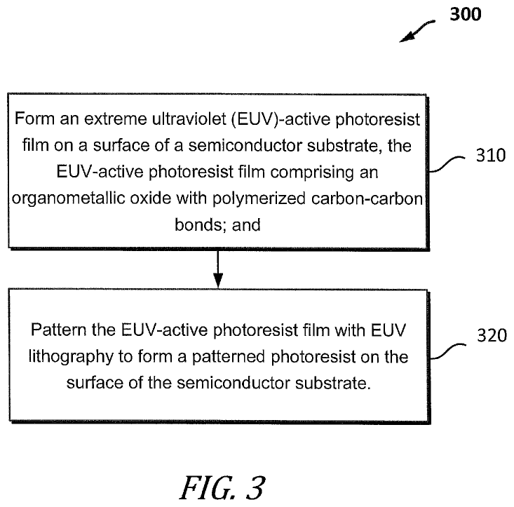

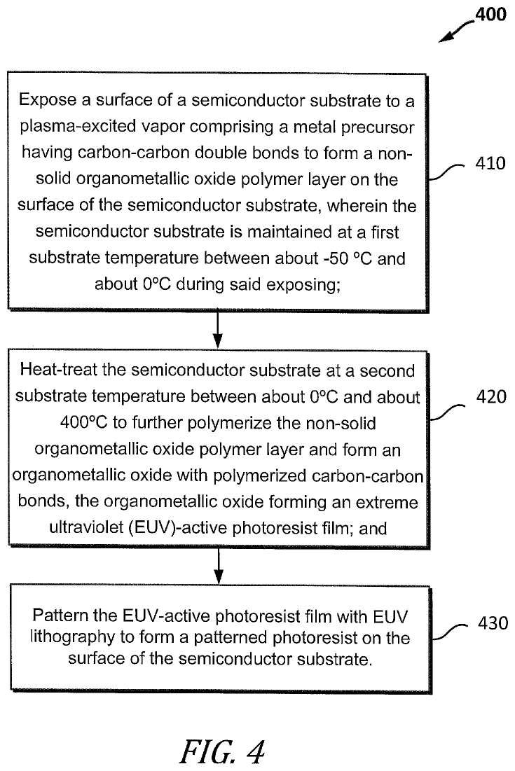

FIGS. 3 and 4 illustrate various embodiments of methods for processing a semiconductor substrate in accordance with the present disclosure. More specifically, FIGS. 3 and 4 provide various embodiments of methods that may be used to form an EUV-active photoresist film, comprising an organometallic oxide polymerized with carbon-carbon bonds, for use in EUV photolithographic processes. It will be recognized that the embodiments of FIGS. 3-4 are merely exemplary and additional methods may utilize the techniques described herein. Further, additional processing steps may be added to the methods shown in the FIGS. 3-4 as the steps described are not intended to be exclusive. Moreover, the order of the steps is not limited to the order shown in the figures as different orders may occur and/or various steps may be performed in combination or at the same time.

FIG. 3 illustrates one embodiment of a method 300 for processing a semiconductor substrate. The method 300 shown in FIG. 3 may generally begin by forming an extreme ultraviolet (EUV)-active photoresist film on a surface of the semiconductor substrate (in step 310). The EUV-active photoresist film formed in step 310 is an organometallic oxide with polymerized carbon-carbon bonds. In some embodiments, the organometallic oxide may contain a central metal atom selected from a group consisting of tin (Sn), zirconium (Zr), indium (In), antimony (Sb), bismuth (Bi), zinc (Zn), hafnium (Hf), aluminum (Al) and combinations thereof. In one example embodiment, the organometallic oxide may contain tin (Sn). After the EUV-active photoresist film is formed in step 310, the method 300 may further include patterning the EUV-active photoresist film with EUV lithography to form a patterned photoresist on the surface of the semiconductor substrate (in step 320).

In some embodiments, the EUV-active photoresist film may be formed in step 310 by: (a) exposing the surface of the semiconductor substrate to a plasma-excited vapor comprising a metal precursor having carbon-carbon double bonds to form a non-solid organometallic oxide polymer layer on the surface of the semiconductor substrate, and (b) heat-treating the semiconductor substrate to further polymerize the non-solid organometallic oxide polymer layer and form the organometallic oxide with polymerized carbon-carbon bonds.

In some embodiments, exposing the surface of the semiconductor substrate to the plasma-excited vapor for polymerization of organic polymer may be performed without exposing the substrate to an oxidizer, such as oxygen (O₂), ozone (O₃), water (H₂O), hydrogen peroxide (H₂O₂), carbon dioxide (CO₂) or carbon monoxide (CO).

In some embodiments, exposing the surface of the semiconductor substrate to the plasma-excited vapor may be performed at relatively low ion energies (for example, less than 50 eV, and more specifically, between about 0 eV and about 5 eV) and relatively low substrate temperatures (for example, less than about 100° C., and more specifically, between about −50° C. and about 0° C.). In such embodiments, the non-solid organometallic oxide polymer layer formed on the substrate surface may include liquid-like oligomer units having carbon-carbon bonds.

In some embodiments, exposing the surface of the semiconductor substrate to the plasma-excited vapor may be performed at relatively high reactive power. When using an organometal precursor of saturated hydrocarbon ligands such as, for example Sn_{α}O_{β} (O—CₘHₙ)ΓCₓH_{y}, (where y=2×+1), reducing the hydrogen partial pressure in the plasma-excited vapor enhances polymerization of the carbon-carbon (C—C) bonds to form the organic film. The reactivity of the plasma-excited vapor is controlled by the RF power. Precursor molecules of Sn_{α}O_{β} (O—CₘHₙ)ΓCₓH_{y} break with high reactive plasma-excited vapor, creating Sn—O—Sn bonds in the photoresist polymer with C—C bonds. The ratio of (—Sn—O—Sn—)/(—C—C—) improves stability and mechanical strength of the organic resist film.

In some embodiments, heat-treating the semiconductor substrate may include maintaining the semiconductor substrate at a substrate temperature between about 0° C. and about 200° C. In other embodiments, heat-treating the semiconductor substrate may include maintaining the semiconductor substrate at a substrate temperature between about 200° C. and about 400° C. During the heat-treating step, the liquid-like oligomer units having carbon-carbon bonds polymerize to form the organometallic oxide with polymerized carbon-carbon bonds.

FIG. 4 illustrates another embodiment of a method 400 for processing a semiconductor substrate. The method 400 shown in FIG. 4 may generally begin by exposing a surface of the semiconductor substrate to a plasma-excited vapor comprising a metal precursor having carbon-carbon double bonds to form a non-solid organometallic oxide polymer layer on the surface of the semiconductor substrate (in step 410). During said exposing, the semiconductor substrate is maintained at a first substrate temperature between about −50° C. and about 0° C. The method 400 may further include heat-treating the semiconductor substrate at a second substrate temperature between about 0° C. and about 400° C. to further polymerize the non-solid organometallic oxide polymer layer and form an organometallic oxide with polymerized carbon-carbon bonds (in step 420). The organometallic oxide formed in step 420 is an extreme ultraviolet (EUV)-active photoresist film. Next, the method 400 may include patterning the EUV-active photoresist film with EUV lithography to form a patterned photoresist on the surface of the semiconductor substrate.

A wide variety of metal precursors may be utilized within the plasma-excited vapor in the methods 300 and 400 shown in FIGS. 3-4. For example, the metal precursor may include a metal alkoxide. In some embodiments, the metal precursor contains tin (Sn) and has the formula Sn_{α}O_{β} (O—CₘHₙ)ΓCₓH_{y}, where m, n, and a are arbitrary integers of 1 or more, β, Γ, x, and y are arbitrary integers of 0 or more, and β and Γ are not 0 at the same time. In one example, the metal precursor may include SnR1(O—R2)₃, SnR1₂(O—R2)₂, or SnHR1(O—R2)₂, where R1: CH₃, C₂H₃, C₃H₅, C₄H₇, or C₆H₆, and R2: CH₃, C₂H₅, C₃H₇, or C₄H₉. In another example, the metal precursor may include SnCH₃^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, or SnCH₃(C₂H₃)(O—CH₃)₂. In other embodiments, the metal precursor contains tin (Sn) and has the formula SnₓC_{y}H_{z}, where x, y, and z are arbitrary integers of 1 or more. For example, the metal precursor may be selected from the group consisting of Sn(CH₃)₄, Sn(C₂H₅)₄, SnH(CH₃)₃, and SnH(C₂H₅)₃. In further embodiments, the metal precursor contains a metal (M) and has the formula M_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time.

In some embodiments, the plasma-excited vapor may include a metal precursor and an additive precursor. For example, when the metal precursor contains tin (Sn) and has the formula Sn_{α}O_{β} (O—CₘHₙ)ΓCₓH_{y}, the additive precursor added to the plasma-excited vapor may contain tin (Sn) and have a formula Sn_{α}CₓH_{y}, where m, n, and α are arbitrary integers of 1 or more. When the metal precursor contains a metal (M) and has the formula M_{α}O_{β} (O—CₘHₙ)ΓCₓH_{y}, the additive precursor added to the plasma-excited vapor may contain a metal (M) and have a formula MαCxHy, where m, n, and α are arbitrary integers of 1 or more.

In some embodiments, the plasma-excited vapor may further include an additive monomer to increase a photo-sensitivity of the EUV-active photoresist film to EUV radiation. In some embodiments, the additive monomer may include a hydrocarbon containing carbon-oxygen double bonds. For example, the additive monomer may include a ketone, an aldehyde, or an ester.

Improved process flows and methods for forming an EUV-active photoresist film, comprising an organometallic oxide polymerized with carbon-carbon bonds, for use in EUV photolithographic processes are described in various embodiments. The process flows and methods disclosed herein improve upon conventional methods of forming EUV-active photoresists by utilizing chemical vapor polymerization (CVP) to deposit metal oxide resist complexes on the substrate surface using a low temperature, low ion energy plasma process. The low temperature, low ion energy plasma process uses a variety of metal precursors having carbon-carbon double bounds to form liquid-like oligomer units on the substrate surface which further polymerize upon heat treatment to form new organometallic compounds with improved mechanical strength and stability compared to conventional EUV-active photoresists. Using the process flows and methods disclosed herein, the new organometallic compounds are formed with excellent uniformity and better nucleation on the underlying surfaces (even hydrophobic surfaces). The process flows and methods disclosed herein also provide faster deposition on hydrophobic surfaces by using CVP to deposit liquid-like oligomer units on the substrate surface, instead of depositing a rigid metal oxide film using traditional CVD or ALD. Although the new organometallic compounds described herein can be deposited at a wide variety of thicknesses (for example, less than 10 nm up to several hundred nm), the process flows and methods disclosed herein may enable a thinner, more uniform photoresist coating to be deposited onto the substrate surface, which in turn, can be used to transfer sub-10 nm features to underlying layers of the substrate.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method of processing a semiconductor substrate, the method comprising:
forming an extreme ultraviolet (EUV)-active photoresist film on a surface of the semiconductor substrate, the EUV-active photoresist film comprising an organometallic oxide with polymerized carbon-carbon bonds; and
patterning the EUV-active photoresist film with EUV lithography to form a patterned photoresist on the surface of the semiconductor substrate.

2. The method of claim 1, wherein the organometallic oxide contains a central metal atom of tin (Sn), zirconium (Zr), indium (In), antimony (Sb), bismuth (Bi), zinc (Zn), hafnium (Hf), or aluminum (Al), or combinations thereof.

3. The method of claim 1, wherein said forming the EUV-active photoresist film comprises:
exposing the surface of the semiconductor substrate to a plasma-excited vapor comprising a metal precursor having carbon-carbon double bonds to form a non-solid organometallic oxide polymer layer on the surface of the semiconductor substrate.

4. The method of claim 3, wherein the non-solid organometallic oxide polymer layer includes liquid-like oligomer units having carbon-carbon bonds.

5. The method of claim 3, wherein said exposing the surface of the semiconductor substrate to the plasma-excited vapor is performed without exposure to oxygen (O₂), ozone (O₃), water (H₂O), hydrogen peroxide (H₂O₂), carbon dioxide (CO₂) or carbon monoxide (CO).

6. The method of claim 3, wherein the metal precursor includes a metal alkoxide.

7. The method of claim 3, wherein the metal precursor contains tin (Sn) and has a formula Sn_{α}O_{β} (O—CₘHₙ)ΓCₓH_{y}, where m, n, and a are arbitrary integers of 1 or more, β, Γ, x, and y are arbitrary integers of 0 or more, and β and Γ are not 0 at the same time.

8. The method of claim 7, wherein the plasma-excited vapor further comprises an additive precursor, and wherein the additive precursor contains tin (Sn) and has a formula Sn_{α}CₓH_{y}, where m, n, and a are arbitrary integers of 1 or more.

9. The method of claim 3, wherein the metal precursor includes SnR1(O—R2)₃, SnR1₂ (O—R2)₂, or SnHR1(O—R2)₂, where R1: CH₃, C₂H₃, C₃H₅, C₄H₇, or C₆H₆, and R2: CH₃, C₂H₅, C₃H₇, or C₄H_{9.}

10. The method of claim 3, wherein the metal precursor includes SnCH₃^{t}Bu(O—^{t}Bu)₂, Sn^{t}Bu(O—^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O—^{t}Bu)₂, or SnCH₃(C₂H₃)(O—CH₃)₂.

11. The method of claim 3, wherein the metal precursor contains tin (Sn) and has a formula SnₓC_{y}H_{z}, where x, y, and z are arbitrary integers of 1 or more.

12. The method of claim 11, wherein the metal precursor includes Sn(CH₃)₄, Sn(C₂H₅)₄, SnH(CH₃)₃, or SnH(C₂H₅)₃.

13. The method of claim 3, wherein the metal precursor contains a metal (M) and has a formula M_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time.

14. The method of claim 13, wherein the plasma-excited vapor further comprises an additive precursor, and wherein the additive precursor contains the metal (M) and has a formula MαCxHy, where m, n, and a are arbitrary integers of 1 or more.

15. The method of claim 3, wherein the plasma-excited vapor further comprises an additive monomer to increase a photo-sensitivity of the EUV-active photoresist film to EUV radiation, and wherein the additive monomer comprises a hydrocarbon containing carbon-oxygen double bonds.

16. The method of claim 15, wherein the additive monomer includes a ketone, an aldehyde, or an ester.

17. The method of claim 3, wherein said exposing the surface of the semiconductor substrate to the plasma-excited vapor comprises:
maintaining an ion energy of about 50 eV, or less, in the plasma-excited vapor; and
maintaining a substrate temperature of less than about 100° C. during the exposing.

18. The method of claim 3, wherein said forming the EUV-active photoresist film further comprises heat-treating the semiconductor substrate to further polymerize the non-solid organometallic oxide polymer layer and form the organometallic oxide with polymerized carbon-carbon bonds.

19. The method of claim 18, wherein said heat-treating includes maintaining the semiconductor substrate at a substrate temperature between about 0° C. and about 200° C.

20. The method of claim 18, wherein said heat-treating includes maintaining the semiconductor substrate at a substrate temperature between about 200° C. and about 400° C.

21. A method of processing a semiconductor substrate, the method comprising:
exposing a surface of the semiconductor substrate to a plasma-excited vapor comprising a metal precursor having carbon-carbon double bonds to form a non-solid organometallic oxide polymer layer on the surface of the semiconductor substrate, wherein the semiconductor substrate is maintained at a first substrate temperature between about −50° C. and about during said exposing;
heat-treating the semiconductor substrate at a second substrate temperature between about 0° C. and about 400° C. to further polymerize the non-solid organometallic oxide polymer layer and form an organometallic oxide with polymerized carbon-carbon bonds, the organometallic oxide forming an extreme ultraviolet (EUV)-active photoresist film; and
patterning the EUV-active photoresist film with EUV lithography to form a patterned photoresist on the surface of the semiconductor substrate.

22. The method of claim 21, wherein the second substrate temperature is between about and about 200° C.

23. The method of claim 21, wherein the second substrate temperature is between about 200° C. and about 400° C.

24. The method of claim 21, wherein the metal precursor includes a metal alkoxide.

25. The method of claim 21, wherein the plasma-excited vapor further comprises an additive monomer to increase a photo-sensitivity of the EUV-active photoresist film to EUV radiation, and wherein the additive monomer comprises a hydrocarbon containing carbon-oxygen double bonds.
